(19) United States
(12) Patent Application Publication
(10) Pub. No.: US 2026/0362981 A1
(43) Pub. Date: Nov. 12, 2026

(54) DISC BENDER TRANSDUCER WITH CENTRAL PLATE WITH FIXED BOUNDARY CONDITION

(71) Applicant: Halliburton Energy Services, Inc., Houston, TX (US)

(72) Inventors: Jing Jin, Singapore (SG); Zeqing Sun, Singapore (SG); Yadong Wang, Singapore (SG)

(73) Assignee: Halliburton Energy Services, Inc., Houston, TX (US)

(21) Appl. No.: 19/205,334

(22) Filed: May 12, 2025

(51) Int. Cl. H10N 30/50; H10N 30/30

(52) U.S. Cl. CPC H10N 30/50; H10N 30/302

(57) ABSTRACT

A transducer that may include a first piezoelectric layer, a second piezoelectric layer, a central plate disposed between the first piezoelectric layer and the second piezoelectric layer, and a boundary the central plate is attached to.

### BACKGROUND

Wellbores drilled into subterranean formations may enable recovery of desirable fluids (e.g., hydrocarbons) using any number of different techniques. Acquiring properties of subterranean formations may enhance the recovery of desirable fluids. Identifying formation properties may be performed by many different systems and methods. One such system and method may capture formation properties by utilizing pressure pulses. Pressure pulses, which may also be referred to as acoustic waves, reflect off different parts of a formation or wellbore. The reflected pressure pulses may form secondary pressure pulses or secondary acoustic waves. In examples, these secondary pressure pulses may be shear velocity waves. Shear velocity waves may provide information on formation properties.

Transducers are a specific device that may be utilized to create pressure waves. Transducers may induce pressure pulses in a forward and rear direction using a disc-bender assembly. A disc-bender is an assembly with multiple piezoelectric discs bonded by epoxy to each other, without any intermediate layer except epoxies and electrodes in between. The disc-bender is mounted in the transmitter by clamping the edges from top and bottom.

### BRIEF DESCRIPTION OF THE DRAWINGS

These drawings illustrate certain aspects of some examples of the present disclosure and should not be used to limit or define the disclosure.

FIG. 1 illustrates an example of a drilling system.

FIG. 2 illustrates an example of a well measurement system.

FIG. 3 illustrates an example of a measurement assembly.

FIG. 4 is a schematic view of a transducer which may comprise of two layers of piezoelectric discs bonded to each other with an epoxy;

FIGS. 5A & 5B illustrate piezoelectric discs vibrating during operation;

FIG. 6 illustrates how piezoelectric discs may be mounted within the transducer;

FIG. 7 is a schematic view of the transducer which may comprise of two layers of piezoelectric discs bonded to a metal shim;

FIG. 8 illustrates how piezoelectric discs bonded to the metal shim may be mounted within the transducer;

FIG. 9 illustrates the transducer that may be utilized to increase the pressure pulse output below 7 kHz;

FIG. 10A-10D illustrate flex within piezoelectric discs in different arrangements of transducer;

FIG. 11 illustrates an example of the transducer with a thicker boundary;

FIG. 12 illustrates an example of the transducer with a mono-morph design;

FIGS. 13A and 13B illustrate an example of the transducer with a bimorph design;

FIG. 14 illustrates an example of the transducer in which four piezoelectric layers may be utilized to increase the displacement of bimorph design;

FIG. 15 illustrates transducer with two piezoelectric discs separated by a spacer;

FIG. 16 illustrates operation of the transducer with two stacks of piezoelectric discs separated by the spacer; and

FIG. 17 illustrates movement of the two stacks of piezoelectric discs separated by the spacer.

### DETAILED DESCRIPTION

Discussed below are systems and methods for the creation and/or use of low frequency transmitters. Low frequency transmitters may be utilized in downhole sonic logging. In examples, disc-benders may be utilized as low frequency transmitters due to their small size to minimize the strength impact to the tool body that may carry the transmitters. The current acoustic output of disc-bender may have an amplitude below 7 kHz. Generally, acoustic output from 1-7 kHz may be utilized to extract the shear velocity in measurement operations. To achieve higher acoustic output below 7 kHz, the disc-benders may have a larger outer diameter for the transducer, which may result in a lower resonant frequency. However, a larger outer diameter for a transducer may not be beneficial as it may weaken mechanical strength, the bottom hole assembly in which the transducer is disposed.

As discussed below, a disc-bender may be designed with a metallic central plate of thickness larger than 0.004″ and smaller than 0.04.″ Additionally, piezo discs may be bonded by epoxy on both sides of the central plate. The central plate may be fixed to the housing of the transducer. This may lower the resonant frequency of the disc-bender of the same form factor. In addition, without clamping on the edge, limiting vibration, the design may produce larger acoustic output. The systems and methods may comprise multiple stacks of piezoelectric disks with special electrical connection to generate acoustic waves of wide frequency range, especially low frequency from 1 to 5 kHz, with a small footprint.

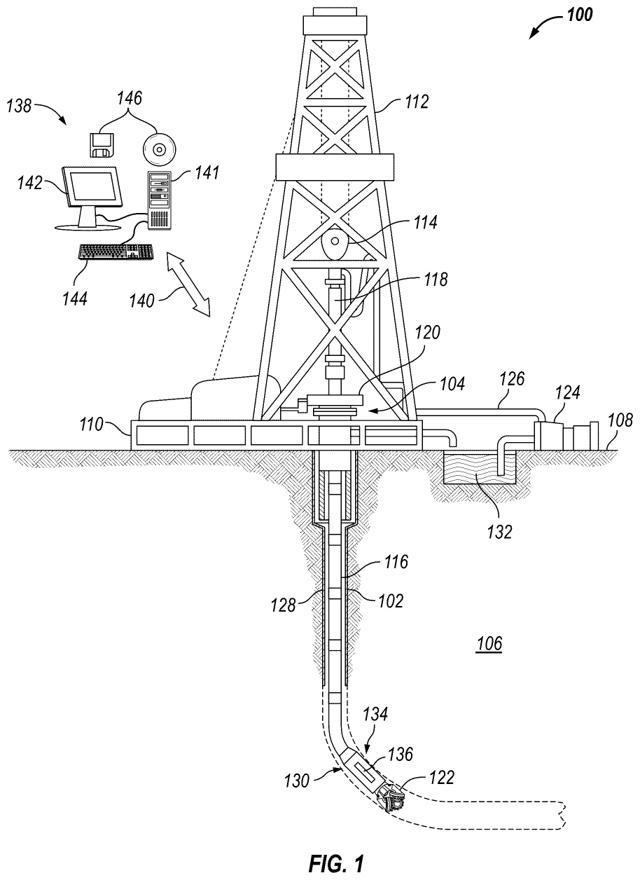

FIG. 1 illustrates a drilling system 100. As illustrated, wellbore 102 may extend from a wellhead 104 into a subterranean formation 106 from a surface 108. Generally, wellbore 102 may include horizontal, vertical, slanted, curved, and other types of wellbore geometries and orientations. Wellbore 102 may be cased or uncased. In examples, wellbore 102 may include a metallic member. By way of example, the metallic member may be a casing, liner, tubing, or other elongated steel tubular disposed in wellbore 102.

As illustrated, wellbore 102 may extend through subterranean formation 106. As illustrated in FIG. 1, wellbore 102 may extend generally vertically into the subterranean formation 106, however wellbore 102 may extend at an angle through subterranean formation 106, such as horizontal and slanted wellbores. For example, although FIG. 1 illustrates a vertical or low inclination angle well, high inclination angle or horizontal placement of the well and equipment may be possible. It should further be noted that while FIG. 1 generally depicts land-based operations, those skilled in the art may recognize that the principles described herein are equally applicable to subsea operations that employ floating or sea-based platforms and rigs, without departing from the scope of the disclosure.

As illustrated, a drilling platform 110 may support a derrick 112 having a traveling block 114 for raising and lowering drill string 116. Drill string 116 may include, but is not limited to, drill pipe and coiled tubing, as generally known to those skilled in the art. A kelly 118 may support drill string 116 as it may be lowered through a rotary table 120. A drill bit 122 may be attached to the distal end of drill string 116 and may be driven either by a downhole motor and/or via rotation of drill string 116 from surface 108. Without limitation, drill bit 122 may include roller cone bits, PDC bits, natural diamond bits, any hole openers, reamers, coring bits, and the like. As drill bit 122 rotates, it may create and extend wellbore 102 that penetrates various subterranean formations 106. A pump 124 may circulate drilling fluid through a feed pipe 126 through kelly 118, downhole through interior of drill string 116, through orifices in drill bit 122, back to surface 108 via annulus 128 surrounding drill string 116, and into a retention pit 132.

With continued reference to FIG. 1, drill string 116 may begin at wellhead 104 and may traverse wellbore 102. Drill bit 122 may be attached to a distal end of drill string 116 and may be driven, for example, either by a downhole motor and/or via rotation of drill string 116 from surface 108. Drill bit 122 may be a part of bottom hole assembly (BHA) 130 at distal end of drill string 116. BHA 130 may further include tools for look-ahead resistivity applications. As will be appreciated by those of ordinary skill in the art, BHA 130 may be a measurement-while drilling (MWD) or logging-while-drilling (LWD) system.

BHA 130 may comprise any number of tools, transmitters, and/or receivers to perform downhole measurement operations. For example, as illustrated in FIG. 1, BHA 130 may include a measurement assembly 134. It should be noted that measurement assembly 134 may make up at least a part of BHA 130. Without limitation, any number of different measurement assemblies, communication assemblies, battery assemblies, and/or the like may form BHA 130 with measurement assembly 134. Additionally, measurement assembly 134 may form BHA 130 itself. In examples, measurement assembly 134 may comprise at least one transducer 136, which may be disposed at the surface of measurement assembly 134. Without limitation, transducer 136 may also be disposed within measurement assembly 134. Without limitation, there may be four transducers 136 that may be disposed ninety degrees from each other. However, it should be noted that there may be any number of transducers 136 disposed along BHA 130 at any degree from each other. Additionally, transducers 136 may be aligned on top of each other and spaced about the axis of BHA 130. Transducers 136 may function and operate to generate an acoustic pressure pulse that travels through wellbore fluids. In examples, transducers 136 may further sense and acquire the reflected pressure wave which is modulated (i.e., reflected as an echo) by the wellbore wall.

During measurement operations, the travel time of the pulse wave from transmission to recording of the echo may be recorded. This information may lead to determining a radius of wellbore 102, which may be derived by the fluid sound speed. By analyzing the amplitude of the echo signal, the acoustic impedance may also be derived. Without limitation, transducers 136 may be made of piezo-ceramic crystals, or optionally magneto strictive materials or other materials that generate an acoustic pulse when activated electrically or otherwise. In examples, transducers 136 may also include backing materials and matching layers. It should be noted that transducers 136 and assemblies housing transducers 136 may be removable and replaceable, for example, in the event of damage or failure.

Without limitation, BHA 130 may be connected to and/or controlled by information handling system 138, which may be disposed on surface 108. Without limitation, information handling system 138 may be disposed downhole in BHA 130. Processing of information recorded may occur downhole and/or on surface 108. Processing occurring downhole may be transmitted to surface 108 to be recorded, observed, and/or further analyzed. Additionally, information recorded on information handling system 138 that may be disposed downhole may be stored until BHA 130 may be brought to surface 108. In examples, information handling system 138 may communicate with BHA 130 through a communication line (not illustrated) disposed in (or on) drill string 116. In examples, wireless communication may be used to transmit information back and forth between information handling system 138 and BHA 130. Information handling system 138 may transmit information to BHA 130 and may receive as well as process information recorded by BHA 130. In examples, a downhole information handling system (not illustrated) may include, without limitation, a microprocessor or other suitable circuitry, for estimating, receiving and processing signals from BHA 130. Downhole information handling system (not illustrated) may further include additional components, such as memory, input/output devices, interfaces, and the like. In examples, while not illustrated, BHA 130 may include one or more additional components, such as analog-to-digital converter, filter and amplifier, among others, which may be used to process the measurements of BHA 130 before they may be transmitted to surface 108. Alternatively, raw measurements from BHA 130 may be transmitted to surface 108.

Any suitable technique may be used for transmitting signals from BHA 130 to surface 108, including, but not limited to, wired pipe telemetry, mud-pulse telemetry, acoustic telemetry, and electromagnetic telemetry. While not illustrated, BHA 130 may include a telemetry subassembly that may transmit telemetry data to surface 108. At surface 108, pressure transducers (not shown) may convert the pressure signal into electrical signals for a digitizer (not illustrated). The digitizer may supply a digital form of the telemetry signals to information handling system 138 via a communication link 140, which may be a wired or wireless link. The telemetry data may be analyzed and processed by information handling system 138.

As illustrated, communication link 140 (which may be wired or wireless, for example) may be provided that may transmit data from BHA 130 to an information handling system 138 at surface 108. Information handling system 138 may include a personal computer 141, a video display 142, a keyboard 144 (i.e., other input devices.), and/or non-transitory computer-readable media 146 (e.g., optical disks, magnetic disks) that can store code representative of the methods described herein. In addition to, or in place of processing at surface 108, processing may occur downhole.

As discussed below, methods may be utilized by information handling system 138 to determine properties of subterranean formation 106. Information may be utilized to produce an image, which may be generated into a two or three-dimensional models of subterranean formation 106. These models may be used for well planning, (e.g., to design a desired path of wellbore 102). Additionally, they may be used for planning the placement of drilling systems within a prescribed area. This may allow for the most efficient drilling operations to reach a subsurface structure. During drilling operations, measurements taken within wellbore 102 may be used to adjust the geometry of wellbore 102 in real time to reach a geological target. Measurements collected from BHA 130 of the formation properties may be used to steer drilling system 100 toward a subterranean formation 106.

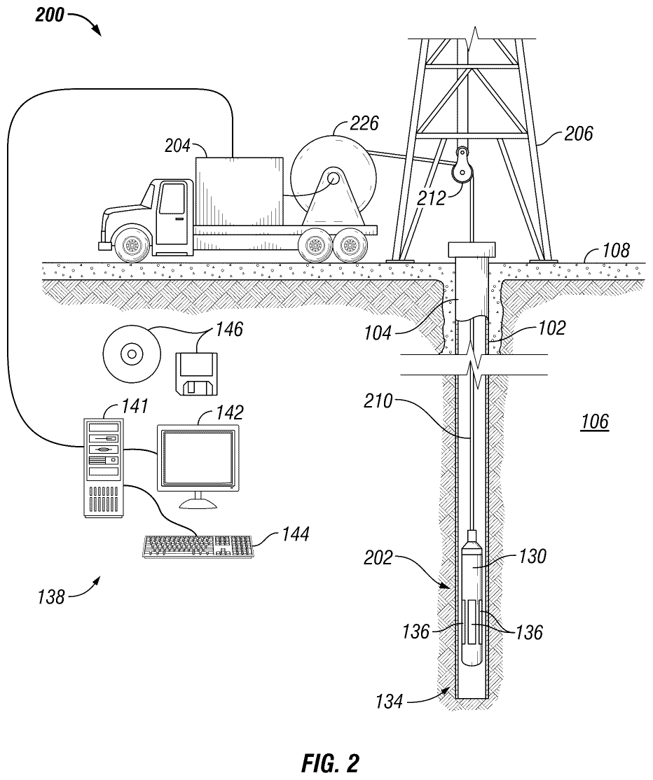

FIG. 2 illustrates a cross-sectional view of a well measurement system 200. As illustrated, well measurement system 200 may comprise downhole tool 202 attached a vehicle 204. In examples, it should be noted that downhole tool 202 may not be attached to a vehicle 204. Downhole tool 202 may be supported by rig 206 at surface 108. Downhole tool 202 may be tethered to vehicle 204 through conveyance 210. Conveyance 210 may be disposed around one or more sheave wheels 212 to vehicle 204. Conveyance 210 may include any suitable means for providing mechanical conveyance for downhole tool 202, including, but not limited to, wireline, slickline, coiled tubing, pipe, drill pipe, downhole tractor, or the like. In some embodiments, conveyance 210 may provide mechanical suspension, as well as electrical and/or optical connectivity, for downhole tool 202. Conveyance 210 may comprise, in some instances, a plurality of electrical conductors and/or a plurality of optical conductors extending from vehicle 204, which may provide power and telemetry. In examples, an optical conductor may utilize a battery and/or a photo conductor to harvest optical power transmitted from surface 108. Conveyance 210 may comprise an inner core of seven electrical conductors covered by an insulating wrap. An inner and outer steel armor sheath may be wrapped in a helix in opposite directions around the conductors. The electrical and/or optical conductors may be used for communicating power and telemetry between vehicle 204 and downhole tool 202. Information from downhole tool 202 may be gathered and/or processed by information handling system 138. For example, signals recorded by transducer 136 may be stored on memory and then processed by downhole tool 202.

The processing may be performed real-time during data acquisition or after recovery of downhole tool 202. Processing may alternatively occur downhole or may occur both downhole and at surface. In some embodiments, signals recorded by downhole tool 202 may be conducted to information handling system 138 by way of conveyance 210. Information handling system 138 may process the signals, and the information contained therein may be displayed for an operator to observe and stored for future processing and reference. Information handling system 138 may also contain an apparatus for supplying control signals and power to downhole tool 202.

Systems and methods of the present disclosure may be implemented, at least in part, with information handling system 138. While shown at surface 108, information handling system 138 may also be located at another location, such as remote from wellbore 102. Information handling system 138 may include any instrumentality or aggregate of instrumentalities operable to compute, estimate, classify, process, transmit, receive, retrieve, originate, switch, store, display, manifest, detect, detect, record, reproduce, handle, or utilize any form of information, intelligence, or data for business, scientific, control, or other purposes. For example, an information handling system 138 may be a personal computer 141, a network storage device, or any other suitable device and may vary in size, shape, performance, functionality, and price. Information handling system 138 may include random access memory (RAM), one or more processing resources such as a central processing unit (CPU) or hardware or software control logic, ROM, and/or other types of nonvolatile memory. Additional components of the information handling system 138 may include one or more disk drives, one or more network ports for communication with external devices as well as various input and output (I/O) devices, such as a keyboard 144, a mouse, and a video display 142. Information handling system 138 may also include one or more buses operable to transmit communications between the various hardware components. Furthermore, video display 142 may provide an image to a user based on activities performed by personal computer 141. For example, producing images of geological structures created from recorded signals. By way of example, video display unit may produce a plot of depth versus the two cross-axial components of the gravitational field and versus the axial component in borehole coordinates. The same plot may be produced in coordinates fixed to the Earth, such as coordinates directed to the North, East and directly downhole (Vertical) from the point of entry to the borehole. A plot of overall (average) density versus depth in borehole or vertical coordinates may also be provided. A plot of density versus distance and direction from the borehole versus vertical depth may be provided. It should be understood that many other types of plots are possible when the actual position of the measurement point in North, East and Vertical coordinates is taken into account. Additionally, hard copies of the plots may be produced in paper logs for further use.

Alternatively, systems and methods of the present disclosure may be implemented, at least in part, with non-transitory computer-readable media 146. Non-transitory computer-readable media 146 may include any instrumentality or aggregation of instrumentalities that may retain data and/or instructions for a period of time. Non-transitory computer-readable media 146 may include, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other electromagnetic and/or optical carriers; and/or any combination of the foregoing.

In examples, rig 206 includes a load cell (not shown) which may determine the amount of pull on conveyance 210 at the surface of wellbore 102. Information handling system 138 may comprise a safety valve (not illustrated) which controls the hydraulic pressure that drives drum 226 on vehicle 204 which may reel up and/or release conveyance 210 which may move downhole tool 202 up and/or down wellbore 102. The safety valve may be adjusted to a pressure such that drum 226 may only impart a small amount of tension to conveyance 210 over and above the tension necessary to retrieve conveyance 210 and/or downhole tool 202 from wellbore 102. The safety valve is typically set a few hundred pounds above the amount of desired safe pull on conveyance 210 such that once that limit is exceeded, further pull on conveyance 210 may be prevented.

As illustrated in FIG. 2, downhole tool 202 may include measurement assembly 134. It should be noted that measurement assembly 134 may make up at least a part of downhole tool 202. Without limitation, any number of different measurement assemblies, communication assemblies, battery assemblies, and/or the like may form downhole tool 202 with measurement assembly 134. Additionally, measurement assembly 134 may form downhole tool 202 itself. In examples, measurement assembly 134 may comprise at least one transducer 136, which may be disposed at the surface of measurement assembly 134. Without limitation, transducer 136 may also be disposed within measurement assembly 134. Without limitation, there may be four transducers 136 that may be disposed ninety degrees from each other. However, it should be noted that there may be any number of transducers 136 disposed along BHA 130 at any degree from each other. Additionally, transducers 136 may be aligned on top of each other and spaced about the axis of BHA 130. Transducers 136 may function and operate to generate an acoustic pressure pulse in the wellbore fluid.

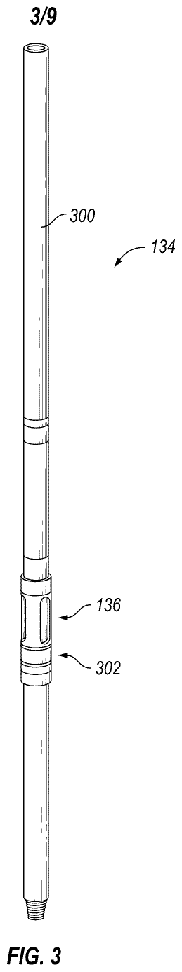

FIG. 3 illustrates an expanded view of measurement assembly 134. As illustrated, measurement assembly 134 may comprise at least one battery section 300 and at least one instrument section 302. Battery section 300 may operate and function to enclose and/or protect at least one battery that may be disposed in battery section 300. Without limitation, battery section 300 may also operate and function to power measurement assembly 134. Specifically, battery section 300 may power at least one transducer 136, which may be disposed at any end of battery section 300 in instrument section 302.

Instrument section 302 may house at least one transducer 136. As described above, transducer 136 may operate and function and operate to generate a pressure pulse that travels through wellbore fluids. The pressure pulse may have a frequency range from 10 Hz ~100 kHz. It should be noted that the pulse signal may be emitted with different frequency content. In examples, transducers 136 may be referred to as a transmitter, which generates a pressure pulse, travelling in the wellbore fluids to interact with wellbore 102 (e.g., referring to FIG. 1). In examples, a pressure pulse may be referred to as an acoustic wave and/or acoustic waves, as seen below. During operations a pressure pulse may reflect any number of surfaces in wellbore 102.

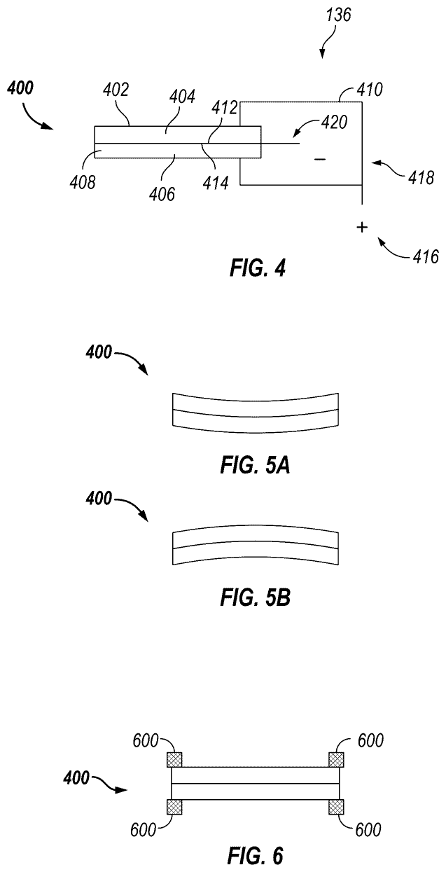

As noted above, pressure pulse may be created by transducer 136. As discussed below, transducer 136 may comprise one or more piezoelectric discs, which may be used to create pressure pulses. FIG. 4 is a schematic view of transducer 136 which may comprise of two layers of piezoelectric discs 400 bonded to each other with an epoxy. Top surface 402 of top piezoelectric layer 404, and bottom surface 406 of bottom piezoelectric layer 408 may be electrically connected by electrical connections 410 to serve as the first electrode 418 of transducer 136. Bottom surface 412 of top piezoelectric layer 404, and top surface 414 of bottom piezoelectric layer 408 may be joined by epoxy to serve as the second electrode 420 of transducer 136. During operation, when power source 416 (e.g., Alternating Current or Direct Current) may be applied to electrical connections 410 and connect to first electrode 418 and/or second electrode 420 of transducer 136, piezoelectric discs 400 may bend due to the electromechanical coupling of the piezoelectric material, and hence converts the electrical energy into mechanical vibration. Piezoelectric discs 400 may vibrate at a greater rate when the frequency of the AC input, from power source 416, coincides with the fundamental resonant frequency of piezoelectric discs 400. The vibrate of piezoelectric discs 400 may allow for transducer 136 to transmit at a frequency range of about 1 kHz to about 100 kHz.

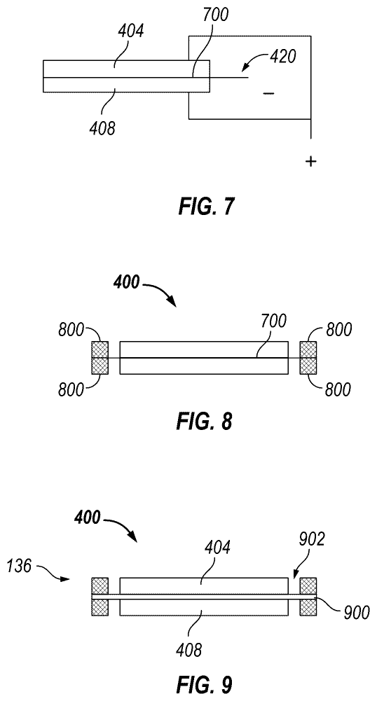

FIGS. 5A & 5B illustrate piezoelectric discs 400 vibrating during operation. FIG. 5A illustrates piezoelectric discs 400 moving in a downward motion and FIG. 5B illustrates piezoelectric discs 400 moving in upward motion. As disclosed above, when power source 416 may be applied (e.g., Alternating Current or Direct Current) piezoelectric discs 400 may bend due to the electromechanical coupling of the piezoelectric material, and hence converts the electrical energy into mechanical vibration. The displacement shown in FIGS. 5A & 5B is amplified by hundred times for illustration purposes and does not represent the actual physical bend of piezoelectric discs 400. In reality, the vertical displacement (along the thickness direction) is of micrometer or sub-micrometer range. When piezoelectric discs 400 are installed into instrument section 302 (e.g., referring to FIG. 3), a typical mounting scheme, as illustrated in FIG. 6, is to utilize a clamp 600 at the top and bottom edges of piezoelectric discs 400. Further, in some cases, a metallic shim 700 may be disposed between top piezoelectric layer 404 and bottom piezoelectric layer 408 to facilitate the connection of second electrode 420 of transducer 136, as shown in FIG. 7. Metallic shim 700 may serve as an electric connection, and hence it is very thin, typically less than about 0.004 inches (about 100 micrometers). With metallic shim 700, transducer 136 may also be mounted into transducer housing 800 (which is disposed within instrument section 302) via metallic shim 700 as shown in FIG. 8. It should be noted that as metallic shim 700 is thin, the mounting doesn't affect the vibration mode, or resonant frequency of piezoelectric discs 400. Hence, disc benders may comprise a metallic shim that may be very thin (usually less than 0.004 inches), in order not to impact the vibration of the disc bender. Because when the metallic shim is thick, pressure pulse output created using metallic shim 700 is reduced, due to the additional mechanical strength of metallic shim 700. An increase in pressure pulse output below 7 kHz is needed to increase measurement resolution in downhole operations.

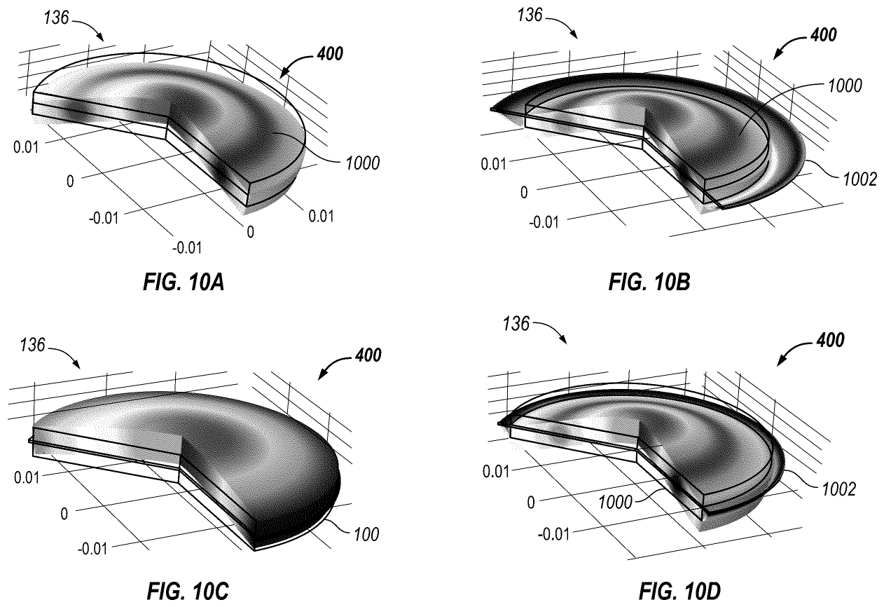

FIG. 9 illustrates transducer 136 that may be utilized to increase the pressure pulse output below 7 kHz, which current transducers are not able to do without increasing their dimensions. To increase pressure pulse output below 7 kHz while keeping the dimension of the transducer, a fixed boundary condition is created by disposing a central plate 900 between top piezoelectric layer 404 and bottom piezoelectric layer 408. In examples, central plate 900 may have a thickness between about 0.004 inches (about 100 micrometers) and about 0.04″ (about 1000 micrometers). During experimentation, any height about above 0.04″ (about 1000 micrometers) for central plate 900 may cause bending and activation of central plate 900 difficult. However, the increase weight of central plate 900 over metallic shim 700 (e.g., referring to FIG. 7) increased the ability for pressure pulse output to be below 7 kHz. For example, the thickness may be between about 0.008 inches (about 200 micrometers) and about 0.02 inches (about 500 micrometers). With continued reference to FIG. 9, central plate 900 may be fixed within a distance 902 from the outer diameter piezoelectric discs 400. As shown, distance 902 may be about 0 to 0.3 inches (about 8 millimeters). For example, about 0.01 inch (about 0.25 millimeters) to about 0.1 inch (about 2.5 millimeters). With the fixed boundary condition, the vibration mode of transducer 136 may be changed, from a free vibration disc with a nodal line (blue) inside the disc (FIG. 10A) to a disc vibrating with fixed edge with the nodal line (blue) at the edge of the disc (FIG. 10C). Due to the increased diameter of the nodal line, the fundamental resonant frequency is reduced.

FIGS. 10A-10D illustrate flex within piezoelectric disc 400 in different arrangements of transducer 136. FIG. 10A illustrates transducer 136 with two piezoelectric disc 400, in which piezoelectric disc 400 may each have about 1.5 inches (about 38 millimeters) in outer diameter and about 0.07 inches (about 2 millimeters) in thickness. It should be noted that FIG. 10A does not have a metallic shim 700 or central plate 900 (e.g., referring to FIGS. 7 and 9). This may create a first resonant frequency is about 14 kHz. As illustrated, a diameter of nodal line 1000 may be smaller than a diameter of piezoelectric disc 400.

In FIG. 10B, metallic shim 700 (not illustrated) may be disposed between piezoelectric disc 400. Piezoelectric discs 400 may each have about 1.5 inches (about 38 millimeters) in outer diameter and about 0.07 inches (about 2 millimeters) in thickness. As illustrated in FIG. 10B, since the shim 700 is thin (less than 0.004″), it does not affect the vibration of piezoelectric disc 400. In this configuration, resonant frequency is about 14 kHz, almost the same as FIG. 10A, and diameter of nodal line 1000 is the same as FIG. 10A as well.

FIG. 10C illustrates an example in which central plate 900 may be disposed between piezoelectric disc 400. Piezoelectric disc 400 may be about 1.5 inches (about 38 millimeters) in outer diameter and about 0.07 inches (about 2 millimeters) in thickness. As illustrated in FIG. 10C, nodal line 1000 is at the outer diameter of piezoelectric discs 400. In this configuration, a different first vibration mode is created. The first resonant frequency may be reduced to about 7 kHz or lower, diameter of nodal line 1000 is the same as the diameter of piezoelectric disc 400, which may be larger than the nodal line 1000 seen in FIGS. 10A and 10B.

FIG. 10D illustrates an example in which central plate 900 may be disposed between piezoelectric disc 400. In this example, the thickness of central plate 900 may be about 0.01 inches (about 0.25 millimeters), which may be fixed at about 0.15 inches (about 4 millimeters) from the outer diameter of piezoelectric discs 400. Piezoelectric disc 400 may have about 1.5 inches (about 38 millimeters) in outer diameter and about 0.07 inches (about 2 millimeters) in thickness. As illustrated in FIG. 10D, nodal 1000 is at about ¾of the outer diameter of piezoelectric disc 400 and further a second nodal 1002, which also represents the least vertical displacement, is shown at the outer edge of piezoelectric discs 400. Thus, central plate 900, which may be fixed at a large distance such as 0.15 inch (about 4 millimeters), from the outer diameter of piezoelectric disc 400 may vibrate relatively freely. In this case, the first vibration mode changes back to the first vibration mode of FIGS. 10A and 10B, and the fundamental resonant frequency turns back to about 14 kHz.

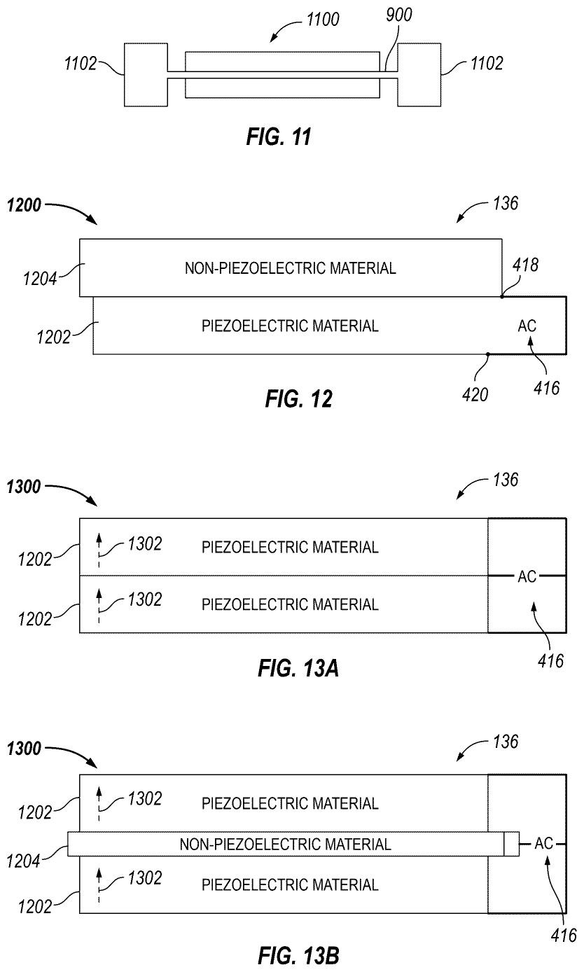

As noted, and discussed above, a fixed boundary condition may be applied to the entire circumference of central plate 900 (e.g., referring to FIG. 9). It should be noted that the fixed boundary condition may be applied to at least a part of the circumference of central plate 900. The fixed boundary condition may be realized by, but not limited to, using epoxy or screw-tightening, or their combination, to fix central plate 900 to a housing, or mounting platform of transducer 136. Alternatively, central plate 900 may be thin at center 1100 where piezoelectric discs 400 may be bonded to, and thick at boundary 1102, beyond the bonding area. It should be noted that in example, boundary 1102 may be the housing of transducer 136. When the thicker region of central plate 900 at boundary 1102 has weight of at least three times of the thiner region at center 1100. Thus, the thiner region becomes fixed to the thick region, and hence the fixed boundary condition is also realized, as illustrated in FIG. 11. The system and methods discussed above may reduce a first resonant frequency, without changing the dimensions of transducer 136. This may be beneficial for designing low frequency piezoelectric discs 400 in transducer 136 for measurement assembly 134 (e.g., referring to FIG. 1) with strigent dimension limitation.

In the above paragraphs, transducer 136 is described with one layer of piezoelectric discs 400. It should be noted that transducer 136 may comprise of more than one layer of piezoelectric discs 400, as long as they are arranged to bend together when the electric input is added, as discussed above. In examples, transducer 136 may comprise one or more forms of piezoelectric discs 400 layering. Referring to FIG. 12, in a first example, transducer 136 may comprise a mono-morph design 1200, where only one layer of piezoelectric material layer 1202 may be utilized. Piezoelectric material layer 1202 may be epoxy-bonded to a non-piezoelectric material 1204, such as metal. When power source 416, such as A/C voltage, is added to first electrode 418 and/or second electrode 420, piezoelectric material layer 1202 may extend or contract with the alternation of the driving voltage and hence causing mono-morph design 1200 to bend upwards or downwards alternatively. The resultant displacement perpendicular to the plane of piezoelectric material layer 1202 may generate acoustic waves if mono-morph design 1200 is immersed in an acoustic medium.

FIGS. 13A and 13B illustrate a second design, bimorph design 1300 that may increase displacement of piezoelectric material layer 1202 of transducer 136 during operations. In this design, two piezoelectric material layers 1202 may be utilized. Each of the piezoelectric material layers 1202 may be epoxy-bonded together without an intermediate layer, as illustrated in FIG. 13A. In another example, as illustrated in FIG. 13B, each of the piezoelectric material layers 1202 may be epoxy-bonded together to a non-piezoelectric intermediate layer 1204. As illustrated in FIGS. 13A and 13B, polarization directions 1302 of the two piezoelectric material layers 1202 may be arranged along the same direction. In this way, power source 416, such as A/C voltage, when added to bimorph design 1300, the in-plane displacements of the two piezoelectric material layers 1202 may be opposite to each other, and hence piezoelectric material layers 1202 of bimorph design 1300 may bend upwards and/or downwards alternatively.

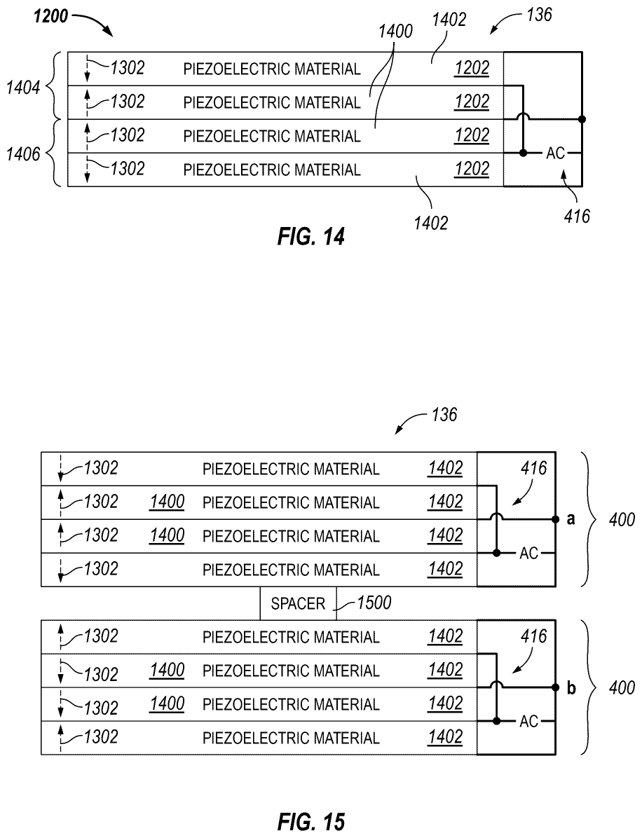

FIG. 14 illustrates an example of transducer 136 in which four piezoelectric material layers 1202 may be utilized to increase the displacement of bimorph design 1300. As illustrated, polarizations 1302 of the four piezoelectric material layers 1202 may be aligned, where center two piezoelectric layers 1400 may have the same polarization 1302, while top piezoelectric layer 1402 and bottom piezoelectric layer 1404 have the opposite polarization 1302 of the center two piezoelectric layers 1400. In this way, when power source 416, such as an A/C voltage, may be applied, the in-plane displacement of top two piezoelectric layers 1404 or bottom two piezoelectric layers 1406 may have the same direction, and the in-plane displacement of top two piezoelectric layers 1404 and bottom two piezoelectric layers 1406 may be in opposite directions. As a result, the four piezoelectric material layers 1202 may bend upwards or downwards alternatively.

With continued reference to FIG. 14, although each layer of the four piezoelectric material layers 1202 may be at least half the thickness of a transducer 136 comprising two piezoelectric layers (e.g., referring got FIGS. 13A & 13B). However, the dimensions of the different embodiments of transducer 136, four-piezoelectric layers vs two-piezoelectric layers, may be nearly identical. The acoustic output of the four piezoelectric layers may be doubled when the same power source 416, such as A/C voltage, may be applied.

Increasing the overall thickness of transducer 136, with a plurality of piezoelectric layers or thicker piezoelectric layers, may increase the resonant frequency (Fr), increase power, of transducer 136. AS noted above, transducer 136 may operate and function efficiently at its Fr. If Fr increases, the acoustic output at low frequency may be reduced. Therefore, to increase the acoustic output, four piezoelectric layers 1402, such as seen in FIG. 14, may be used in place of two piezoelectric layer 1402, as seen in FIGS. 13A & 13B. As overall thickness is similar, a low Fr may be maintained. Additionally, it should be noted that the output amplitude may increase further with more piezoelectric layers 1402 while maintaining the overall thickness of transducer 136.

FIG. 15 illustrates transducer 136 with two piezoelectric discs 400 separated by a spacer 1500, where each piezoelectric discs 400 may comprise a plurality of piezoelectric layers 1402. In examples, each piezoelectric disc 400 may have different number of piezoelectric layers 1402. It should be noted that piezoelectric discs 400 may be referred to as “stacks.” As illustrated, each piezoelectric discs 400 may comprise four piezoelectric layers 1402 separated by spacer 1500. It should be noted spacer 1500 is not connected to an outer housing of transducer 136. The “stack” may be fixed to the outer housing of transducer 136 by clamping at an edge of the bottom stack. In other examples, central plate 900 (e.g., referring to FIG. 9) may be disposed within the “stacks.” Central plate 900 may be attached to the outer housing of transducer 136. Additionally, there may be a plurality of piezoelectric discs 400, all separated by spacer 1500. Spacer 1500 may be made of common materials such as metals, plastics, and/or ceramics. Generally, spacer 1500 may have a diameter that may be smaller than ⅓of the diameter of piezoelectric discs 400, but large enough to avoid breaking. The height of spacer 1500 may be larger than about 0.01 inch (about 0.25 mm) to avoid touching between each “stack” while each stack is vibrating. As illustrated, spacer 1500 may be centered between the outer diameter of piezoelectric layers 1402. However, spacer 1500 may be off centered to about a third of the radius from the center of the piezoelectric layers 1402 to the outer diameter of piezoelectric layers 1402. During operations, spacer 1500 may separating piezoelectric discs 400, which may allow each piezoelectric disc 400 to bend relatively independent of each other. If there is no such spacer 1500, and each piezoelectric disc 400 is connected to each other, then a single piezoelectric disc 400 may be formed, which may increase the overall thickness. This will cause the single piezoelectric disc 400 difficulty in bending. Hence the output amplitude may be reduced. In addition, the Fr of transducer 136 may increase due to the increase thickness, and hence the output amplitude at low frequency may be reduced.

Each piezoelectric layer 1402 of piezoelectric discs 400 may have a polarization of 1302. Polarizations 1302 of the four piezoelectric material layers 1202 may be aligned, where center two piezoelectric layers 1400 may have the same polarization 1302, while top piezoelectric layer 1402 and bottom piezoelectric layer 1404 have the opposite polarization 1302 of the center two piezoelectric layers 1400. In this way, when power source 416, such as an A/C voltage, may be applied, the in-plane displacement of top two piezoelectric layers 1404 or bottom two piezoelectric layers 1406 may have the same direction, and the in-plane displacement of top two piezoelectric layers 1404 and bottom two piezoelectric layers 1406 may be in opposite directions.

When power source 416 is applied, such as an A/C voltage, piezoelectric discs 400 may bend according to input frequency of the A/C signal. As illustrated in FIG. 15, power source 416 may be unified. Thus, a common input from power source 416 may be used to drive multiple piezoelectric discs 400. This may save cost when creating measurement assembly 134 (e.g., referring to FIG. 1). However, separate power source 416 in puts may be used to drive piezoelectric discs 400 differently, which may for example increase acoustic output at different frequency bandwidth.

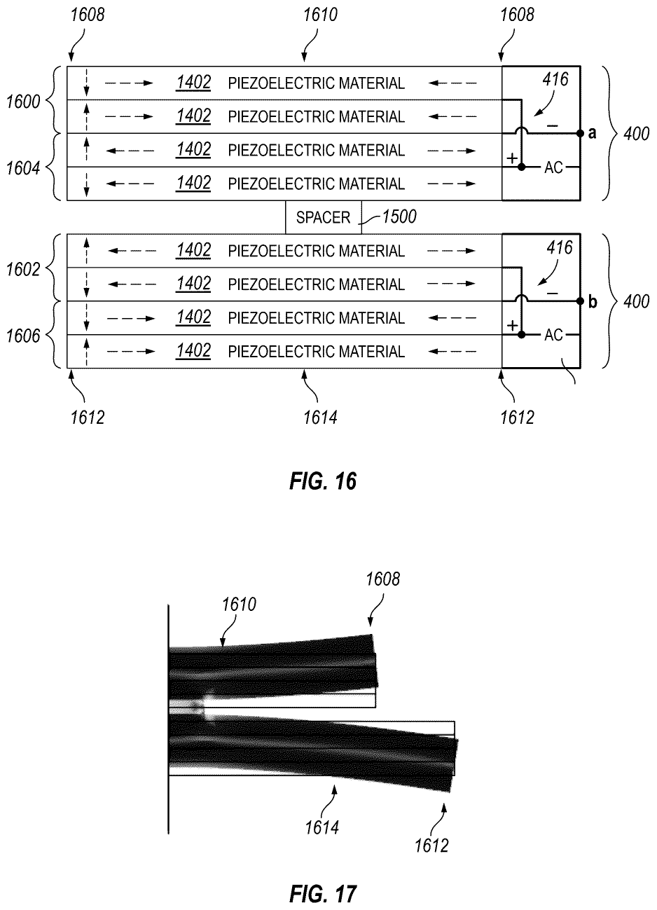

FIG. 16 illustrates operation of transducer 136 with two stacks of piezoelectric discs 400 separated by a spacer 1500, where each piezoelectric discs 400 may comprise a plurality of piezoelectric layers 1402. During operation, when power source 416, such as an AC voltage, is applied, such that a first pair 1600 of piezoelectric layers 1402 and a second pair 1602 of piezoelectric layers 1402 are negative. Additionally, a third pair 1604 of piezoelectric layers 1402 and a fourth pair 1606 of piezoelectric layers 1402 are positive. As illustrated in FIGS. 16 and 17, this may cause bending of each piezoelectric disc 400. For example, edges 1608 of top piezoelectric disc 1610 may bend upwards, while edges 1612 of bottom piezoelectric disc 1614 may bend downwards.

Improvements over current technology are found in the introduction of a central plate in which the assembly is mounted to. In this assembly, the vibration mode of the free disc changes and the nodal line is moved toward the edge. With the increased diameter of the nodal line, the resonant frequency of the disc bender is reduced, and hence the transducer may output higher acoustic energy at low frequencies. In addition, as the nodal line has moved to the edge, all of the vertical displacement of the disc bender is in phase. This is in contrast to current technology in which current disc benders without a fixed boundary condition may have a vertical displacement at two sides of the nodal line, which may be out of phase. The in-phase displacement of the disc bender helps to increase the acoustic output throughout the working frequency range, for example, 1 to 100 kHz.

The preceding description provides various embodiments of systems and methods of use which may contain different method steps and alternative combinations of components.
Statement 1. A transducer that may comprise a first piezoelectric layer, a second piezoelectric layer, a central plate disposed between the first piezoelectric layer and the second piezoelectric layer, and a boundary the central plate is attached to.
Statement 2: The transducer of statement 1, wherein the central plate has a thickness between about 0.008 inches to about 0.02 inches.
Statement 3: The transducer of any previous statements 1 or 2, further comprising a distance between an outer diameter of the first piezoelectric layer and the boundary, wherein the boundary is the transducer housing or a structure in which the central plate is attached to.
Statement 4: The transducer of statement 3, wherein the distance is about be about 0 inch to about 0.3 inches.
Statement 5: The transducer of any previous statements 1-3, wherein the boundary has a weight equal to or more than three times the weight of the central plate.
Statement 6: The transducer of any previous statements 1-3 or 5, wherein the first piezoelectric layer and the second piezoelectric layer are bonded to the central plate.
Statement 7: The transducer of any previous statements 1-3, 5, or 6, wherein the first piezoelectric layer and the second piezoelectric layer form a piezoelectric disc.
Statement 8: The transducer of statement 7, wherein the piezoelectric disc has an outer diameter about 1.5 inches.
Statement 9: The transducer of statements 7 or 8, wherein the piezoelectric disc has about 0.07 inches in thickness.
Statement 10: The transducer of any previous statements 1-3, 5, 6, or 7, wherein the transducer has an output below 7 kHz.
Statement 11: A transducer that may comprise a first stack, a second stack, a spacer disposed between the first stack and the second stack, and a transducer housing the spacer is attached to.
Statement 12: The transducer of statement 11, wherein the first stack comprises a plurality of piezoelectric material layers.
Statement 13: The transducer of statement 12, wherein each of the plurality of piezoelectric material layers have a polarization.
Statement 14: The transducer of statement 13, wherein at least a part of the plurality of piezoelectric material layers have the polarization arranged along a same direction.
Statement 15: The transducer of any previous statements 12 or 13, wherein each of the plurality of piezoelectric material layers are bonded to each other.
Statement 16: The transducer of any previous statements 11 or 12, wherein the second stack comprises a plurality of piezoelectric material layers.
Statement 17: The transducer of statement 16, wherein each of the plurality of piezoelectric material layers are bonded to each other.
Statement 18: The transducer of any previous statements 16 or 17, wherein each of the plurality of piezoelectric material layers have a polarization.
Statement 19: The transducer of statement 18, wherein at least a part of the plurality of piezoelectric material layers have the polarization arranged along a same direction.
Statement 20: The transducer of any previous statements 11, 12, or 16, wherein the spacer is a metal, a plastic, or a ceramic.

It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the elements that it introduces.

Therefore, the present examples are well adapted to attain the ends and advantages mentioned as well as those that are inherent therein. The particular examples disclosed above are illustrative only, and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A transducer comprising:
a first piezoelectric layer;
a second piezoelectric layer;
a central plate disposed between the first piezoelectric layer and the second piezoelectric layer; and
a boundary the central plate is attached to.

2. The transducer of claim 1, wherein the central plate has a thickness between about 0.008 inches to about 0.02 inches.

3. The transducer of claim 1, further comprising a distance between an outer diameter of the first piezoelectric layer and the boundary, wherein the boundary is the transducer housing or a structure in which the central plate is attached to.

4. The transducer of claim 3, wherein the distance is about be about 0 inch to about 0.3 inches.

5. The transducer of claim 1, wherein the boundary has a weight equal to or more than three times the weight of the central plate.

6. The transducer of claim 1, wherein the first piezoelectric layer and the second piezoelectric layer are bonded to the central plate.

7. The transducer of claim 1, wherein the first piezoelectric layer and the second piezoelectric layer form a piezoelectric disc.

8. The transducer of claim 7, wherein the piezoelectric disc has an outer diameter about 1.5 inches.

9. The transducer of claim 7, wherein the piezoelectric disc has about 0.07 inches in thickness.

10. The transducer of claim 1, wherein the transducer has an output below 7 kHz.

11. A transducer comprising:
a first stack;
a second stack;
a spacer disposed between the first stack and the second stack; and
a transducer housing the spacer is attached to.

12. The transducer of claim 11, wherein the first stack comprises a plurality of piezoelectric material layers.

13. The transducer of claim 12, wherein each of the plurality of piezoelectric material layers have a polarization.

14. The transducer of claim 13, wherein at least a part of the plurality of piezoelectric material layers have the polarization arranged along a same direction.

15. The transducer of claim 12, wherein each of the plurality of piezoelectric material layers are bonded to each other.

16. The transducer of claim 11, wherein the second stack comprises a plurality of piezoelectric material layers.

17. The transducer of claim 16, wherein each of the plurality of piezoelectric material layers are bonded to each other.

18. The transducer of claim 16, wherein each of the plurality of piezoelectric material layers have a polarization.

19. The transducer of claim 18, wherein at least a part of the plurality of piezoelectric material layers have the polarization arranged along a same direction.

20. The transducer of claim 11, wherein the spacer is a metal, a plastic, or a ceramic.
